(19) United States
(12) Patent Application Publication
(10) Pub. No.: US 2010/0224939 A1
(43) Pub. Date: Sep. 9, 2010

(54) SEMICONDUCTOR DEVICE

(76) Inventors: Ju-youn Kim, Seoul (KR); Bong-seok Kim, Seongnam-si (KR); Il-ryong Kim, Seoul (KR); Cheong-sik Yu, Seoul (KR); Ki-young Kim, Hwaseong-si (KR); Yu-jin Jeon, Seongnam-si (KR)

Correspondence Address: F. CHAU & ASSOCIATES, LLC, 130 WOODBURY ROAD, WOODBURY, NY, 11797, US

(21) Appl. No.: 12/716,914

(22) Filed: Mar. 3, 2010

(30) Foreign Application Priority Data
Mar. 5, 2009 (KR) 10-2009-0018911

(51) Int. Cl. H01L 27/092; H01L 29/78

(52) U.S. Cl. 257/369; 257/288; 257/E27.062; 257/E29.255

(57) ABSTRACT

Provided is a metal-oxide semiconductor (MOS) transistor containing a metal gate pattern. The semiconductor device includes a p-channel metal-oxide semiconductor (PMOS) transistor including a semiconductor substrate, a first insulating film formed on the semiconductor substrate, a first metal gate conductive film formed on the first insulating film, and a nitrogen diffusion blocking film formed between the first insulating film and the first metal gate conductive film, and an n-channel metal-oxide semiconductor (NMOS) transistor including the semiconductor substrate, a second insulating film formed on the semiconductor substrate, a second metal gate conductive film formed on the second insulating film, and a reaction blocking film formed of metal nitride and formed between the second insulating film and the second metal gate conductive film. According to the inventive concept, a reaction between a metal gate film and an insulating film may be minimized so as to result in a highly reliable MOS transistor.

### CROSS-REFERENCE TO RELATED APPLICATION

This application claims the benefit of Korean Patent Application No. 10-2009-0018911, filed on Mar. 5, 2009, in the Korean Intellectual Property Office, the disclosure of which is incorporated herein in its entirety by reference.

### BACKGROUND

The inventive concept relates to a semiconductor device, and more particularly, to a metal-oxide semiconductor (MOS) transistor containing a metal gate pattern.

To improve the reliability of transistors in an integrated circuit, research has been conducted to increase the operating speed and functionality of a semiconductor device and also decrease the power consumption thereof.

### SUMMARY

The inventive concept provides a semiconductor device including a metal-oxide semiconductor (MOS) transistor having excellent reliability.

According to an aspect of the inventive concept, there is provided a semiconductor device comprising p-channel metal-oxide semiconductor (PMOS) and n-channel metal-oxide semiconductor (NMOS) transistors.

The PMOS transistor may include a semiconductor substrate, a first insulating film formed on the semiconductor substrate, a first metal gate conductive film formed on the first insulating film, and a nitrogen diffusion blocking film formed between the first insulating film and the first metal gate conductive film. The NMOS transistor may include the semiconductor substrate, a second insulating film formed on the semiconductor substrate, a second metal gate conductive film formed on the second insulating film, and a reaction blocking film formed of metal nitride and formed between the second insulating film and the second metal gate conductive film. The metal nitride may be nitrogen-rich metal nitride in which the content of nitrogen is greater than the content of stoichiometric nitrogen. The first and second insulating films may include one selected from the group consisting of silicon oxide (SiO₂), silicon oxynitride (SiOₓ₁N_{y1}), hafnium oxide (HfO₂), hafnium oxynitride (HfOₓ₂N_{y2}), hafnium silicon oxide (HfSiₓ₃O_{y3}), hafnium silicon oxynitride (HfSiₓ₄O_{y4}N_{z4}), zirconium oxide (ZrO₂), zirconium oxynitride (ZrOₓ₅N_{y5}), zirconium silicon oxide (ZrSiₓ₆O_{y6}), zirconium silicon oxynitride (ZrSiₓ₇O_{y7}N_{z7}), tantalum oxide (Ta₂O₅), tantalum oxynitride (TaOₓ₈N_{y8}), tantalum silicon oxide (TaSiₓ₉O_{y9}), tantalum silicon oxynitride (TaSiₓ₁₀O_{y10}N_{z10}), aluminum oxide (Al₂O₃), aluminum oxynitride (AlOₓ₁₁N_{y11}), aluminum silicon oxide (AlSiₓ₁₂O_{y12}), aluminum silicon oxynitride (AlSiₓ₁₃O_{y13}N_{z13}), titanium oxide (TiO₂), titanium oxynitride (TiOₓ₁₄N_{y14}), titanium silicon oxide (TiSiₓ₁₅O_{y15}), titanium silicon oxynitride (TiSiₓ₁₆O_{y16}N_{z16}), and combinations thereof, wherein the subscripts “x1” to “z16” indicate any positive real number, respectively.

The nitrogen diffusion blocking film may include metal carbide or nitrogen-free metal. In particular, the metal carbide or the nitrogen-free metal may include titanium (Ti), tantalum (Ta), titanium silicide (TiSi), or tantalum silicide (TaSi).

The nitrogen-rich metal nitride may include Ti or Ta.

The semiconductor device may further include a capping layer formed directly on or under the first and second insulating films, wherein the capping layer is an oxide film comprising lanthanum (La), aluminum (Al), or magnesium (Mg).

The semiconductor substrate under the first and second insulating films may include silicon carbide (SiC) or silicon germanium (SiGe).

The first and second metal gate conductive films may include the same material or different materials. For example, the first and second metal gate conductive films may include one selected from the group consisting of tantalum (Ta), titanium (Ti), titanium nitride (TiN), tungsten (W), nickel (Ni), tantalum silicon (TaSi), tungsten silicon (WSi), titanium silicon (TiSi), molybdenum silicon (MoSi), nickel silicon (NiSi), ruthenium (Ru), ruthenium oxide (RuO), iridium (Ir), iridium oxide (IrO), and platinum (Pt).

The PMOS transistor may further comprise the reaction blocking film formed between the nitrogen diffusion blocking film and the first metal gate conductive film. The reaction blocking film of the PMOS transistor may be positioned higher on the semiconductor substrate than the reaction blocking film of the NMOS transistor.

According to an aspect of the inventive concept, a p-channel metal-oxide semiconductor (PMOS) transistor comprises a semiconductor substrate, a gate insulating film formed on the semiconductor substrate, a metal gate conductive film formed on the gate insulating film, and a nitrogen diffusion blocking film formed between the gate insulating film and the metal gate conductive film.

The nitrogen diffusion blocking film may comprise metal carbide or nitrogen-free metal. The metal carbide or the nitrogen-free metal may comprise titanium (Ti), tantalum (Ta), titanium silicide (TiSi), or tantalum silicide (TaSi).

The PMOS transistor may further comprises a reaction blocking film formed of metal nitride and formed between the nitrogen diffusion blocking film and the metal gate conductive film.

According to an aspect of the inventive concept, an n-channel metal-oxide semiconductor (NMOS) transistor comprises, a semiconductor substrate, a gate insulating film formed on the semiconductor substrate, a metal gate conductive film formed on the gate insulating film, and a reaction blocking film formed of metal nitride and formed between the gate insulating film and the metal gate conductive film.

The metal nitride may be nitrogen-rich metal nitride in which the content of nitrogen is greater than the content of stoichiometric nitrogen, and may comprise Ti or Ta.

According to the inventive concept, a reaction between a metal gate film and an insulating film may be minimized so as to realize a highly reliable MOS transistor.

### BRIEF DESCRIPTION OF THE DRAWINGS

Exemplary embodiments of the inventive concept will be more clearly understood from the following detailed description taken in conjunction with the accompanying drawings in which:

FIG. 1 is a cross-sectional diagram of a gate of a conventional p-channel metal-oxide semiconductor (PMOS) transistor;

FIG. 2 is a cross-sectional diagram of a gate according to an embodiment of the inventive concept;

FIG. 3 is a cross-sectional diagram of a gate of a conventional n-channel metal-oxide semiconductor (NMOS) transistor;

FIG. 4 is a cross-sectional diagram of a gate according to an embodiment of the inventive concept; and

FIGS. 5 through 9 are cross-sectional diagrams for describing a method of forming a semiconductor device according to an embodiment of the inventive concept.

### DETAILED DESCRIPTION OF THE EMBODIMENTS

Reference will now be made in more detail to exemplary embodiments, examples of which are illustrated in the accompanying drawings. However, the inventive concept is not limited to the embodiments illustrated hereinafter, and the embodiments herein are introduced in an effort to provide a complete understanding of the scope and spirit of the inventive concept. In the drawings, the thicknesses of layers and regions may be exaggerated for clarity.

It will be understood that when an element, such as a layer, a region, or a substrate, is referred to as being “on”, “connected to” or “coupled to” another element, it may be directly on, connected or coupled to the other element or intervening elements may be present. Like reference numerals may refer to like elements throughout.

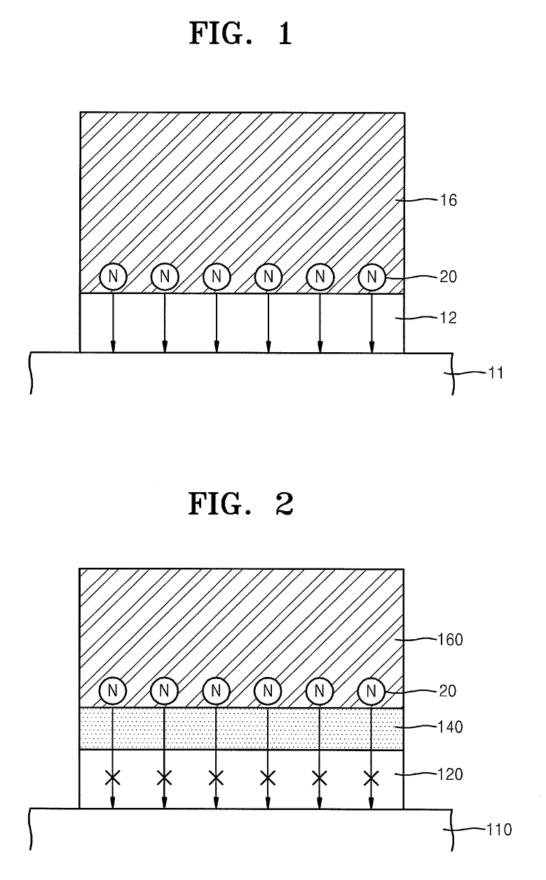

FIG. 1 is a cross-sectional diagram of a gate of a conventional p-channel metal-oxide semiconductor (PMOS) transistor.

Referring to FIG. 1, a gate insulating film 12 is formed on a semiconductor substrate 11 and then a gate conductive film 16 is formed on the gate insulating film 12. The gate insulating film 12 should maintain a thin equivalent oxide film thickness and sufficiently reduce a leakage current between channel regions of the gate conductive film 16 and the semiconductor substrate 11. Thus, metal oxide having a high permittivity is mostly used to form the gate insulating film 12. Also, in some cases, metal oxynitride having a high permittivity may be used.

The gate conductive film 16 may be a metal-containing film. The gate conductive film 16 may be formed by using a physical vapor deposition (PVD) method, a chemical vapor deposition (CVD) method, or an atomic layer deposition (ALD) method. A nitrogen gas may be used as a reaction gas or a carrier gas in the PVD method, the CVD method, or the ALD method or may be contained in a process atmosphere for manufacturing a semiconductor device.

Thus, in most cases, nitrogen atoms and/or molecules 20 are contained in the gate conductive film 16. In a following process performed at high temperature, the nitrogen atoms and/or molecules 20 may be diffused into the gate insulating film 12 and thus the gate insulating film 12 may react with the nitrogen atoms and/or molecules 20. Due to the reaction, an interface trap may occur and fixed oxide charges may also occur.

Such a phenomenon may be a main cause of negative bias temperature instability (NBTI) deterioration of a PMOS transistor. In general, if a negative bias is applied to a gate of a transistor while increasing a temperature of the transistor, in order to perform a stress test of a semiconductor device, an NBTI phenomenon occurs in the transistor and thus the electrical characteristics of the semiconductor device deteriorate. The NBTI phenomenon is caused by a hole trap at an interface between a Si film and a gate insulating film in an active region when a semiconductor device operates. In particular, a variation range of a threshold voltage Vth due to NBTI deterioration is increased in a PMOS transistor more than in an n-channel metal-oxide semiconductor (NMOS) transistor.

FIG. 2 is a cross-sectional diagram of a gate, for example, of a p-channel metal-oxide semiconductor (PMOS) transistor, according to an embodiment of the inventive concept.

Referring to FIG. 2, a gate insulating film 120 is formed on a semiconductor substrate 110 and then a gate conductive film 160 is formed on the gate insulating film 120. A nitrogen diffusion blocking film 140 is formed between the gate insulating film 120 and the gate conductive film 160.

Examples of the semiconductor substrate 110 include a silicon (Si) substrate, a silicon-on-insulator (SOI) substrate, a germanium (Ge) substrate, a germanium -on-insulator (GOI) substrate, and an Si-Ge substrate.

The gate insulating film 120 should maintain a thin equivalent oxide film thickness and sufficiently reduce a leakage current between channel regions of the gate conductive film 160 and the semiconductor substrate 110. Thus, metal oxide having a high permittivity is mostly used to form the gate insulating film 120. Also, in some cases, metal oxynitride having a high permittivity may be used. Examples of a material for forming the gate insulating film 120 include silicon oxide (SiO₂), silicon oxynitride (SiOₓ₁N_{y1}), hafnium oxide (HfO₂), hafnium oxynitride (HfOₓ₂N_{y2}), hafnium silicon oxide (HfSiₓ₃O_{y3}), hafnium silicon oxynitride (HfSiₓ₄O_{y4}N_{z4}), zirconium oxide (ZrO₂), zirconium oxynitride (ZrOₓ₅N_{y5}), zirconium silicon oxide (ZrSiₓ₆O_{y6}), zirconium silicon oxynitride (ZrSiₓ₇O_{y7}N_{z7}), tantalum oxide (Ta₂O₅), tantalum oxynitride (TaOₓ₈N_{y8}), tantalum silicon oxide (TaSiₓ₉O_{y9}), tantalum silicon oxynitride (TaSiₓ₁₀O_{y10}N_{z10}), aluminum oxide (Al₂O₃), aluminum oxynitride (AlOₓ₁₁N_{y11}), aluminum silicon oxide (AlSiₓ₁₂O_{y12}), aluminum silicon oxynitride (AlSiₓ₁₃O_{y13}N_{z13}), titanium oxide (TiO₂), titanium oxynitride (TiOₓ₁₄N_{y14}), titanium silicon oxide (TiSiₓ₁₅O_{y15}), titanium silicon oxynitride (TiSiₓ₁₆O_{y16}N_{z16}), and combinations thereof, wherein the subscripts “x1” to “z16” indicate any positive real number, respectively.

The gate conductive film 160 may be a metal-containing film, and may contain one selected from the group consisting of, for example, tantalum (Ta), titanium (Ti), titanium nitride (TiN), tungsten (W), nickel (Ni), tantalum silicon (TaSi), tungsten silicon (WSi), titanium silicon (TiSi), molybdenum silicon (MoSi), nickel silicon (NiSi), ruthenium (Ru), ruthenium oxide (RuO), iridium (Ir), iridium oxide (IrO), and platinum (Pt).

The nitrogen diffusion blocking film 140 formed between the gate conductive film 160 and the gate insulating film 120 prevents nitrogen atoms and/or molecules 20 contained in the gate conductive film 160 from being diffused into the gate insulating film 120. The nitrogen diffusion blocking film 140 may be formed of metal carbide or nitrogen-free pure metal. For example, the metal carbide or the nitrogen-free pure metal may contain a Ti-based material, a Ta-based material, a titanium silicide (TiSiₘ)-based material, or a tantalum silicide (TaSiₙ)-based material, wherein the subscripts “m” and “n” indicate any positive real number, respectively.

Thus, since the nitrogen diffusion blocking film 140 is disposed between the gate conductive film 160 and the gate insulating film 120, the increase in a variation range of a threshold voltage Vth due to NBTI deterioration may be prevented. In particular, such improvement is greater in a PMOS transistor than in an NMOS transistor.

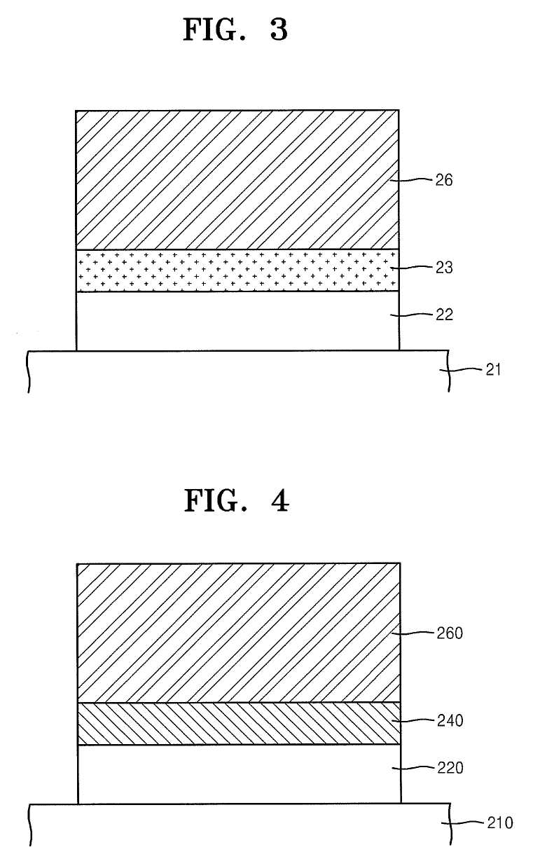

FIG. 3 is a cross-sectional diagram of a gate of a conventional NMOS transistor.

Referring to FIG. 3, a gate insulating film 22 is formed on a semiconductor substrate 21 and then a gate conductive film 26 is formed on the gate insulating film 22. The gate insulating film 22 should maintain a thin equivalent oxide film thickness and sufficiently reduce a leakage current between channel regions of the gate conductive film 26 and the semiconductor substrate 21. Thus, metal oxide having a high permittivity is mostly used to form the gate insulating film 21. Also, in some cases, metal oxynitride having a high permittivity may be used. The gate conductive film 26 may be a metal-containing film. If the gate conductive film 26 contains metal, a reaction layer 23 may be formed on an interface between the gate conductive film 26 and the gate insulating film 22 due to reaction with the gate insulating film 22. As such, an oxygen vacancy in the gate insulating film 22 is increased. Thus, a trap site may occur in the gate insulating film 22 and fixed oxide charges may also occur.

Such a phenomenon may be a cause of a positive bias temperature instability (PBTI) deterioration of an NMOS transistor. In general, if a positive bias is applied to a gate of a transistor while increasing a temperature of the transistor, in order to perform a stress test of a semiconductor device, a PBTI phenomenon occurs in the transistor and thus the electrical characteristics of the semiconductor device deteriorate.

FIG. 4 is a cross-sectional diagram of a gate, for example, of an NMOS transistor, according to an embodiment of the inventive concept.

Referring to FIG. 4, a gate insulating film 220 is formed on a semiconductor substrate 210 and then a gate conductive film 260 is formed on the gate insulating film 220. Meanwhile, a reaction blocking film 240 is formed between the gate insulating film 220 and the gate conductive film 260.

Examples of the semiconductor substrate 210 include an Si substrate, an SOI substrate, a Ge substrate, a GOI substrate, and an Si—Ge substrate.

The gate insulating film 220 should maintain a thin equivalent oxide film thickness and sufficiently reduce a leakage current between channel regions of the gate conductive film 260 and the semiconductor substrate 210. Thus, metal oxide having a high permittivity is mostly used to form the gate insulating film 220. Also, in some cases, metal oxynitride having a high permittivity may be used. Examples of a material for forming the gate insulating film 220 include silicon oxide (SiO₂), silicon oxynitride (SiOₓ₁N_{y1}), hafnium oxide (HfO₂), hafnium oxynitride (HfOₓ₂N_{y2}), hafnium silicon oxide (HfSiₓ₃O_{y3}), hafnium silicon oxynitride (HfSiₓ₄O_{y4}N_{z4}), zirconium oxide (ZrO₂), zirconium oxynitride (ZrOₓ₅N_{y5}), zirconium silicon oxide (ZrSiₓ₆O_{y6}), zirconium silicon oxynitride (ZrSiₓ₇O_{y7}N_{z7}), tantalum oxide (Ta₂O₅), tantalum oxynitride (TaOₓ₈N_{y8}), tantalum silicon oxide (TaSiₓ₉O_{y9}), tantalum silicon oxynitride (TaSiₓ₁₀O_{y10}N_{z10}), aluminum oxide (Al₂O₃), aluminum oxynitride (AlOₓ₁₁N_{y11}), aluminum silicon oxide (AlSiₓ₁₂O_{y12}), aluminum silicon oxynitride (AlSiₓ₁₃O_{y13}N_{z13}), titanium oxide (TiO₂), titanium oxynitride (TiOₓ₁₄N_{y14}), titanium silicon oxide (TiSiₓ₁₅O_{y15}), titanium silicon oxynitride (TiSiₓ₁₆O_{y16}N_{z16}), and combinations thereof, wherein the subscripts “x1” to “z16” indicate any positive real number, respectively.

The gate conductive film 260 may be a metal-containing film, and may contain one selected from the group consisting of for example, Ta, Ti, TiN, W, Ni, TaSi, WSi, TiSi, MoSi, NiSi, Ru, RuO, Ir, IrO, and Pt.

The reaction blocking film 240 formed between the gate conductive film 260 and the gate insulating film 220 may be formed of metal nitride. The metal nitride may be nitrogen-rich metal nitride in which the content of nitrogen is greater than the content of stoichiometric nitrogen. In this case, “stoichiometric” may be understood as including a general (thermodynamically stable) quantitative correlation between metal and nitrogen in a compound formed of metal and nitrogen.

For example, if the metal is Ti, the stoichiometric metal nitride is TiN. However, in nitrogen-rich titanium nitride (TiNₓ), in which the content of nitrogen is greater than the content of stoichiometric nitrogen, x is greater than 1. Alternatively, if the metal is Ta, the stoichiometric metal nitride is tantalum nitride (TaN). However, in nitrogen-rich tantalum nitride (TaN_{y}), in which the content of nitrogen is greater than the content of stoichiometric nitrogen, y is greater than 1.

Since the reaction blocking film 240 is disposed between the gate conductive film 260 and the gate insulating film 220, the effects of PBTI deterioration may be prevented. In particular, such improvement is greater in an NMOS transistor than in a PMOS transistor.

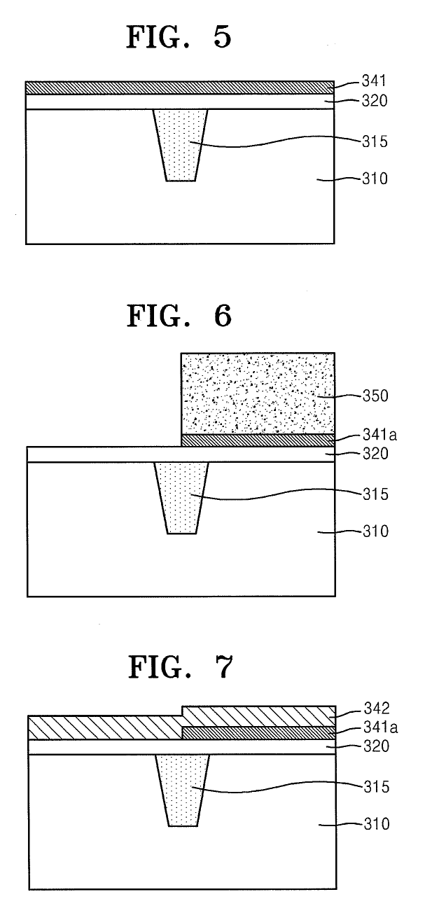

FIGS. 5 through 9 are cross-sectional diagrams for sequentially describing a method of forming a semiconductor device according to an embodiment of the inventive concept.

Referring to FIG. 5, a gate insulating film 320 is formed on a semiconductor substrate 310. The semiconductor substrate 310 may include an NMOS region on which an NMOS transistor is to be formed and a PMOS region on which a PMOS transistor is to be formed. The NMOS and PMOS regions may be isolated from each other by a device isolation film 315. Hereinafter, it is assumed that the NMOS region is formed at a left side of the device isolation film 315 and the PMOS region is formed at a right side of the device isolation film 315.

Examples of the semiconductor substrate 310 include an Si substrate, an SOI substrate, a Ge substrate, a GOI substrate, and an Si-Ge substrate. A gate channel may contain silicon carbide (SiC) or silicon germanium (SiGe) in order to control a bandgap of the gate channel or to improve mobility of the gate channel. Also, nitrogen (N) ion injection and/or fluorine (F) ion injection may be performed in order to control a threshold voltage Vth of the gate channel.

The gate insulating film 320 should maintain a thin equivalent oxide film thickness and sufficiently reduce a leakage current between channel regions of a gate conductive film 360a, 360b (in FIG. 9) and the semiconductor substrate 310. Thus, metal oxide having a high permittivity is mostly used to form the gate insulating film 320. Also, in some cases, metal oxynitride having a high permittivity may be used. Examples of a material for forming the gate insulating film 320 include silicon oxide (SiO₂), silicon oxynitride (SiOₓ₁N_{y1}), hafnium oxide (HfO₂), hafnium oxynitride (HfOₓ₂N_{y2}), hafnium silicon oxide (HfSiₓ₃O_{y3}), hafnium silicon oxynitride (HfSiₓ₄O_{y4}N_{z4}), zirconium oxide (ZrO₂), zirconium oxynitride (ZrOₓ₅N_{y5}), zirconium silicon oxide (ZrSiₓ₆O_{y6}), zirconium silicon oxynitride (ZrSiₓ₇O_{y7}N_{z7}), tantalum oxide (Ta₂O₅), tantalum oxynitride (TaOₓ₈N_{y8}), tantalum silicon oxide (TaSiₓ₉O_{y9}), tantalum silicon oxynitride (TaSiₓ₁₀O_{y10}N_{z10}), aluminum oxide (Al₂O₃), aluminum oxynitride (AlOₓ₁₁N_{y11}), aluminum silicon oxide (AlSiₓ₁₂O_{y12}), aluminum silicon oxynitride (AlSiₓ₁₃O_{y13}N_{z13}), titanium oxide (TiO₂), titanium oxynitride (TiOₓ₁₄N_{y14}), titanium silicon oxide (TiSiₓ₁₅O_{y15}), titanium silicon oxynitride (TiSiₓ₁₆O_{y16}N_{z16}), and combinations thereof, wherein the subscripts “x1” to “z16” indicate any positive real number, respectively.

A nitrogen diffusion blocking film 341 is formed on a whole surface of the gate insulating film 320 including the NMOS and PMOS regions. The nitrogen diffusion blocking film 341 prevents nitrogen atoms and/or molecules contained in the gate conductive film 360a, 360b (in FIG. 9) from being diffused into the gate insulating film 320. The nitrogen diffusion blocking film 341 may be formed of, for example, metal carbide or nitrogen-free pure metal. For example, the metal carbide or the nitrogen-free pure metal may contain a Ti-based material, a Ta-based material, a titanium silicide (TiSiₘ)-based material, or a tantalum silicide (TaSiₙ)-based material, wherein the subscripts “m” and “n” indicate any positive real number, respectively. The gate insulating film 320 may be formed of, for example, a hafnium silicon oxide (HfSiO)-based material.

Referring to FIG. 6, a photoresist pattern 350 is formed on the nitrogen diffusion blocking film 341 to cover the PMOS region, and then an exposed portion of the nitrogen diffusion blocking film 341 is etched by using the photoresist pattern 350 as a mask, thereby forming a nitrogen diffusion blocking film pattern 341a only on the PMOS region.

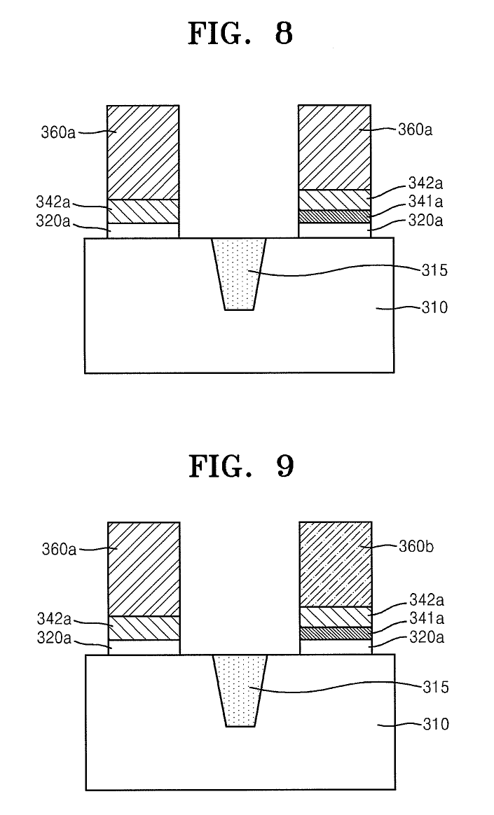

Referring to FIG. 7, a reaction blocking film 342 is formed on a whole surface of a structure formed on the semiconductor substrate 310 including the PMOS and NMOS regions. The reaction blocking film 342 may be formed of metal nitride. The metal nitride may be nitrogen-rich metal nitride in which the content of nitrogen is greater than the content of stoichiometric nitrogen.

For example, if the metal is Ti, the stoichiometric metal nitride is TiN. However, in nitrogen-rich titanium nitride (TiNx), in which the content of nitrogen is greater than the content of stoichiometric nitrogen, x is greater than 1. Alternatively, if the metal is Ta, the stoichiometric metal nitride is TaN. However, in nitrogen-rich tantalum nitride (TaNx), in which the content of nitrogen is greater than the content of stoichiometric nitrogen, x is greater than 1.

Due to the nitrogen diffusion blocking film pattern 341a, the reaction blocking film 342 may be formed to be higher on the PMOS region than on the NMOS region.

Referring to FIG. 8, a gate conductive film (not shown) is formed on a whole surface of the reaction blocking film 342. The gate conductive film may be a metal-containing film, and may contain one selected from the group consisting of, for example, Ta, Ti, TiN, W, Ni, TaSi, WSi, TiSi, MoSi, NiSi, Ru, RuO, Ir, IrO, and Pt.

Continuously, a gate pattern structure is formed by patterning the gate insulating film 320, the nitrogen diffusion blocking film pattern 341a, the reaction blocking film 342, and the gate conductive film, which are formed on the semiconductor substrate 310. Thus, a gate insulating film pattern 320a, a reaction blocking film pattern 342a, and a gate conductive film pattern 360a are formed on the NMOS region, and the gate insulating film pattern 320a, the nitrogen diffusion blocking film pattern 341a, the reaction blocking film pattern 342a, and the gate conductive film pattern 360a are formed on the PMOS region.

Although the gate conductive film patterns 360a on the NMOS and PMOS regions are formed of the same material in FIG. 8, as illustrated in FIG. 9, the gate conductive film pattern 360a on the NMOS region and a gate conductive film pattern 360b on the PMOS region may be formed of different materials.

Although not shown in FIGS. 8 and 9, a capping layer may further be formed directly on or under the gate insulating film 320 and may be an oxide film containing, for example, lanthanum (La), aluminum (Al), or magnesium (Mg).

While the inventive concept has been particularly shown and described with reference to exemplary embodiments thereof, it will be understood that various changes in form and details may be made therein without departing from the spirit and scope of the inventive concept as illustrated in the following claims.

What is claimed is:

1. A semiconductor device comprising p-channel metal-oxide semiconductor (PMOS) and n-channel metal-oxide semiconductor (NMOS) transistors,
wherein the PMOS transistor comprises:
a semiconductor substrate;
a first insulating film formed on the semiconductor substrate;
a first metal gate conductive film formed on the first insulating film; and
a nitrogen diffusion blocking film formed between the first insulating film and the first metal gate conductive film,
wherein the NMOS transistor comprises:
the semiconductor substrate;
a second insulating film formed on the semiconductor substrate;
a second metal gate conductive film formed on the second insulating film; and
a reaction blocking film formed of metal nitride and formed between the second insulating film and the second metal gate conductive film.

2. The semiconductor device of claim 1, wherein the nitrogen diffusion blocking film comprises metal carbide or nitrogen-free metal.

3. The semiconductor device of claim 2, wherein the metal carbide or the nitrogen-free metal comprises titanium (Ti), tantalum (Ta), titanium silicide (TiSi), or tantalum silicide (TaSi).

4. The semiconductor device of claim 1, wherein the metal nitride is nitrogen-rich metal nitride and comprises Ti or Ta.

5. The semiconductor device of claim 1, wherein the first and second insulating films comprise one selected from the group consisting of silicon oxide (SiO₂), silicon oxynitride (SiOₓ₁N_{y1}), hafnium oxide (HfO₂), hafnium oxynitride (HfOₓ₂N_{y2}), hafnium silicon oxide (HfSiₓ₃O_{y3}), hafnium silicon oxynitride (HfSiₓ₄O_{y4}N_{z4}), zirconium oxide (ZrO₂), zirconium oxynitride (ZrOₓ₅N_{y5}), zirconium silicon oxide (ZrSiₓ₆O_{y6}), zirconium silicon oxynitride (ZrSiₓ₇O_{y7}N_{z7}), tantalum oxide (Ta₂O₅), tantalum oxynitride (TaOₓ₈N_{y8}), tantalum silicon oxide (TaSiₓ₉O_{y9}), tantalum silicon oxynitride (TaSiₓ₁₀O_{y10}N_{z10}), aluminum oxide (Al₂O₃), aluminum oxynitride (AlOₓ₁₁N_{y11}), aluminum silicon oxide (AlSiₓ₁₂O_{y12}), aluminum silicon oxynitride (AlSiₓ₁₃O_{y13}N₁₃), titanium oxide (TiO₂), titanium oxynitride (TiOₓ₁₄N_{y14}), titanium silicon oxide (TiSiₓ₁₅O_{y15}), titanium silicon oxynitride (TiSiₓ₁₆O_{y16}N_{z16}), and combinations thereof, wherein the subscripts x1 to z16 are positive real numbers.

6. The semiconductor device of claim 1, further comprising a capping layer formed directly on or under the first and second insulating films, wherein the capping layer is an oxide film comprising lanthanum (La), aluminum (Al), or magnesium (Mg).

7. The semiconductor device of claim 1, wherein the semiconductor substrate under the first and second insulating films comprises silicon carbide (SiC) or silicon germanium (SiGe).

8. The semiconductor device of claim 1, wherein the first and second metal gate conductive films comprise the same material.

9. The semiconductor device of claim 1, wherein the first and second metal gate conductive films comprise different materials.

10. The semiconductor device of claim 1, wherein the first and second metal gate conductive films comprise one selected from the group consisting of tantalum (Ta), titanium (Ti), titanium nitride (TiN), tungsten (W), nickel (Ni), tantalum silicon (TaSi), tungsten silicon (WSi), titanium silicon (TiSi), molybdenum silicon (MoSi), nickel silicon (NiSi), ruthenium (Ru), ruthenium oxide (RuO), iridium (Ir), iridium oxide (IrO), and platinum (Pt).

11. The semiconductor device of claim 1, wherein the metal nitride is nitrogen-rich metal nitride in which the content of nitrogen is greater than the content of stoichiometric nitrogen.

12. The semiconductor device of claim 1, wherein the PMOS transistor further comprises the reaction blocking film formed between the nitrogen diffusion blocking film and the first metal gate conductive film.

13. The semiconductor device of claim 12, wherein the reaction blocking film of the PMOS transistor is positioned higher on the semiconductor substrate than the reaction blocking film of the NMOS transistor.

14. A p-channel metal-oxide semiconductor (PMOS) transistor comprising:
a semiconductor substrate;
a gate insulating film formed on the semiconductor substrate;
a metal gate conductive film formed on the gate insulating film; and
a nitrogen diffusion blocking film formed between the gate insulating film and the metal gate conductive film.

15. The PMOS transistor of claim 14, wherein the nitrogen diffusion blocking film comprises metal carbide or nitrogen-free metal.

16. The PMOS transistor of claim 15, wherein the metal carbide or the nitrogen-free metal comprises titanium (Ti), tantalum (Ta), titanium silicide (TiSi), or tantalum silicide (TaSi).

17. The PMOS transistor of claim 14, further comprising a reaction blocking film formed of metal nitride and formed between the nitrogen diffusion blocking film and the metal gate conductive film.

18. An n-channel metal-oxide semiconductor (NMOS) transistor comprising:
a semiconductor substrate;
a gate insulating film formed on the semiconductor substrate;
a metal gate conductive film formed on the gate insulating film; and
a reaction blocking film formed of metal nitride and formed between the gate insulating film and the metal gate conductive film.

19. The NMOS transistor of claim 18, wherein the metal nitride is nitrogen-rich metal nitride in which the content of nitrogen is greater than the content of stoichiometric nitrogen.

20. The NMOS transistor of claim 18, wherein the metal nitride is nitrogen-rich metal nitride and comprises Ti or Ta.
